(19) United States
(12) Patent Application Publication
(10) Pub. No.: US 2006/0164272 A1
(43) Pub. Date: Jul. 27, 2006

(54) Analog-to-digital-converter comprising a sigma-delta-modulator and receiver with such analog-to-digital-converter

(76) Inventors: Kathleen Jeanne Petrus Philips, Eindhoven (NL); Petrus Antonius Cornelis Maria Nuijten, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/562,272

(22) PCT Filed: Jun. 24, 2004
(86) PCT No.: PCT/IB04/51003

§ 371 Date: Dec. 22, 2005

(30) Foreign Application Priority Data
Jun. 27, 2003 (EP) 03101928.4

(51) Int. Cl. H03M 3/00

(52) U.S. Cl. 341/143

(57) ABSTRACT

Analog-to-digital converter including a sigma-delta modulator (SD) with noise shaping filtering. Signal transfer filtering is introduced in the feedback loop of the sigma-delta modulator. This may be done without affecting the noise shaping filtering e.g. with a signal transfer filter (L) in the forward path of the feedback loop and a complementary signal transfer path (H) in the feedback path of the loop. The analog-to-digital converter may be used for channel filtering, FM-demodulation and/or image rejection in communication receivers.

The invention relates to an analog-to-digital-converter comprising a sigma-delta modulator for analog to digital converting analog input signals, said sigma-delta modulator including a feedback loop with a forward path and a feedback path, wherein the forward path comprises a summing node with a first input receiving the analog input signals, noise-shaping filtering means coupled to the output of said summing node and a quantizer coupled to the output of the noise-shaping filtering means and wherein the feedback path is connected to supply output signals of the quantizer to a second input of the summing node. Such analog-to digital converters are well known in the art and they are e.g. used in receivers receiving a plurality of communication channels, in which a mixer is provided for frequency converting at least part of the communication channels and in which the analog-to-digital converter serves to convert the output signals of the mixer into a digital signal. A receiver of this kind is e.g. known from the article “A 10.7-MHz IF-to-Baseband ΣΔ A/D Conversion System for AM/FM Radio Receivers” of E. J. van der Zwan et al in IEEE Journal of Solid State Circuits, Vol. 35, No 12, December 2000.

The above referenced known receiver comprises between the mixer output and the input of the sigma delta modulator a low-pass or band-pass filter for passing the desired communication channel and for suppressing the undesired neighboring channel(s). A great disadvantage of this kind of receivers is that severe requirements are to be set to the channel filter. The filter should add a minimum amount of noise and signal distortion and it should be of sufficiently high order to suppress the neighboring interferers. In order to avoid these disadvantages of the channel filter prior to the analog to digital conversion, a more popular approach is to place the channel filtering function in the digital domain after the analog to digital converter. In this concept use is made of the fact that digital filtering can nowadays be performed more economically and accurately than analog filtering. However, one disadvantage thereof is that the sample rate of the analog to digital conversion should be high enough to avoid aliazing of the interferers into the desired channel. A second disadvantage is that the dynamic range of the analog to digital converter has to be very large (e.g. 100 dB), inter alias because the interferers in the output of the mixer may have levels that are far greater than the level of the desired channel. The consequence is that in the analog to digital converter and in the digital circuitry thereafter the sample rate and/or the number of bits per sample have to be chosen very large. The power consumption of the analog-to-digital-converter and the digital circuitry thereafter will therefore be large. Moreover non-linear distortion in the analog-to-digital-converter may easily occur. In order to make the disadvantages of the prior art receiver more acceptable, the abovementioned document also proposes to have part of the channel filtering before the analog-to-digital-converter and the other part of the channel filtering behind the analog-to-digital-converter.

It is one object of the present invention to substantially mitigate the fore mentioned problems and the analog-to-digital converter according to the invention is therefore characterized in that both the forward path and the feedback path have filtering means that are arranged to additionally constitute a filtering signal transfer function. More particularly it is an object of the invention to provide a receiver comprising means for receiving a plurality of communication channels, a mixer for frequency-converting at least part of said communication channels and an analog-to-digital-converter as described above for analog to digital converting output signals of the mixer, wherein the signal transfer function of the sigma delta modulator has a pass band that substantially corresponds with the frequency band of the desired channel while the interferer channels beyond that pass band are substantially attenuated. A major objective of the invention is that the channel selection filtering can be much simpler implemented within the loop of the ΣΔ-modulator then when this filtering would be done in front of this loop. The channel filtering has to prevent that large interferers in the neighborhood of the desired channel over-load the τΔ modulator and this may be implemented far easier and with lower noise factor within the feedback loop where the signals are substantially reduced with respect to the signals in front of the feedback loop. The usually rather small signal to noise ratio that is required for the digital post-processing can now easily be obtained by a low order single-bit analog ΣΔ converter with low over sampling also because the digital decimation filter that usually follows the ΣΔ-modulator further suppresses remnants of the neighbor-channels. Moreover an advantage of a single bit ΣΔ converter is that for the quantizer a simple one-level comparator can be used and the digital to analog converter in the feedback path between the comparator and the input-summing node can then often be simplified.

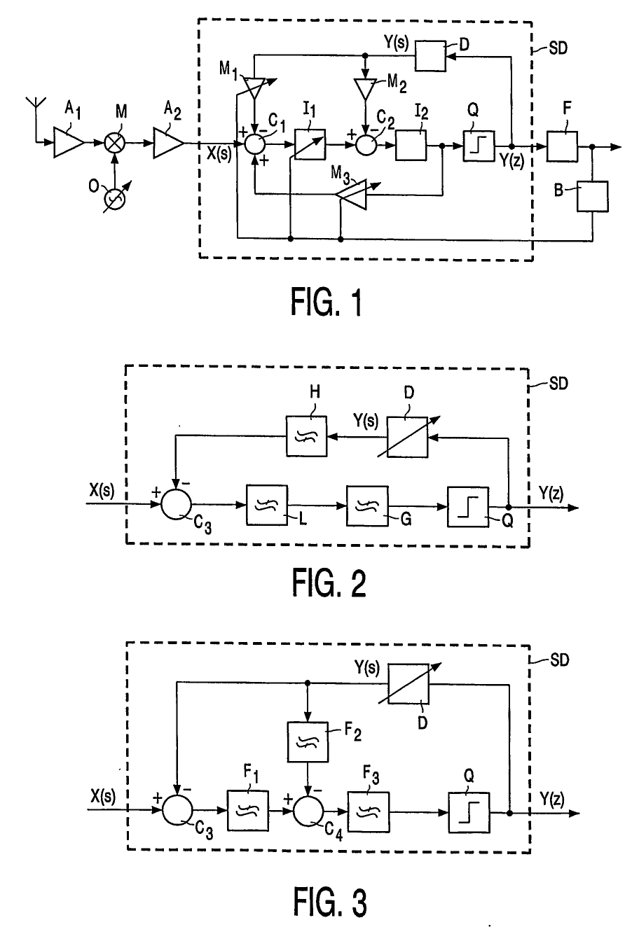

It is quite possible in an arrangement according to the invention to combine the noise shaping function and the channel filtering function in a single filter arrangement. An example thereof will be given in FIG. 1 of the present application. However preferably the filter means for the channel filtering and those for the noise shaping are separated, so that they each may be optimized independently from each other. An example of a receiver with such implementation is characterized in that the forward path of the feedback loop comprises, in addition to said noise shaping filtering means, a first filter for constituting the filtering signal transfer function, that the feedback path of the feedback loop comprises a second filter for constituting the filtering signal transfer function and that the product of the transfer function of the first filter and the transfer function of the second filter is substantially frequency-independent.

Another embodiment of a receiver according to the invention which also has the possibility to independently design the channel filtering and the noise shaping is characterized by a second summing node with first and second inputs and an output, by a first filter with transfer function F₁(s) connected between the output of the first mentioned summing node and the first input of the second summing node, a second filter with transfer function F₂(s) connected between the output of the quantizer and the second input of the second summing node and a third filter with transfer function F₃(s) between the output of the second summing node and the input of the quantizer, wherein the transfer function F₁(s)/(F₁(s)+F₂(s)) provides the filtering signal transfer function of the analog-to-digital converter. When in this implementation the sum F₁(s)+F₂(s) of the transfer functions of the first and second filters is equal to 1, these two filters, which are then complements of each other, perform together the channel filtering and the third filter does the noise shaping.

As is already observed earlier, one of the objects of the present invention is to reduce the dynamic range of the signals generated by the analog to digital converter and consequently to reduce the complexity of the digital circuitry that has to process these signals. A further reduction of the dynamic range can be obtained by a properly designed automatic gain control and the receiver of the present invention may therefore be further characterized in that the feedback loop of the sigma-delta modulator comprises one or more gain controlled stages. The dynamic range may also be reduced by an AGC-stage in front of the ΣΔ-modulator but it may be advantageous to carry out the automatic gain control within the feedback loop of the ΣΔ-modulator because the stage is then to a lesser extent subject to large interferer signals so that the linearity requirements are less severe.

The analog-to-digital converter with in-loop signal transfer filtering according to the present invention cannot only be used for passing signals within the frequency band of interest and rejecting the signals outside this frequency band, but also for filtering within this frequency band of interest. A first example thereof is in a so called “low IF” receiver where image channels tend to leak into the wanted channel. In that case the mixer preceding the analog-to-digital converter has to deliver polyphase (complex) signals and the ΣΔ modulator has to be implemented to handle polyphase (complex) signals. All the filters, the quantizer and the DA-converter have to be implemented to handle polyphase signals. The second filter, which is complementary to the first filter again serves to preserve the loop stability of the ΣΔ modulator. The benefit of the image reject filtering within the loop of the ΣΔ modulator is that its implementation can be easier with lower power consumption and lesser chip area. It may be noted that the polyphase filters can realize both the bandpass filtering to reject neighboring channels and the image-reject filtering.

Another example of filtering within the frequency band of interest is in a receiver for FM-modulated signals which is characterized in that, for the purpose of FM-demodulation of the signal, one of the first and second filters is a differentiator and the other of the first and second filters is an integrator within the frequency band of the input signal. In that case the differentiator-integrator combination converts the FM-modulated signal into an AM modulated digital signal which can then easily be demodulated in the digital processing after the analog-to-digital converter. Again the benefit of the filtering inside the loop of the EA modulator is an easier implementation with lower power consumption and lesser chip area.

It may further be observed that the invention may be implemented with a time-continuous analog ΣΔ-modulator or with a time-discrete analog ΣΔ-modulator (a switched capacitance implementation). In the latter case an anti-aliazing low pass filter that suppresses all frequency components above half the sampling frequency, has to be placed prior to the ΣΔ-modulator.

The invention will be described with reference to the accompanying figures. Herein shows:

FIG. 1 a receiver according to the invention with a first example of a sigma delta modulator according to the invention,

FIG. 2 a second example of a sigma delta modulator according to the invention,

FIG. 3 a third example of a sigma delta modulator according to the invention,

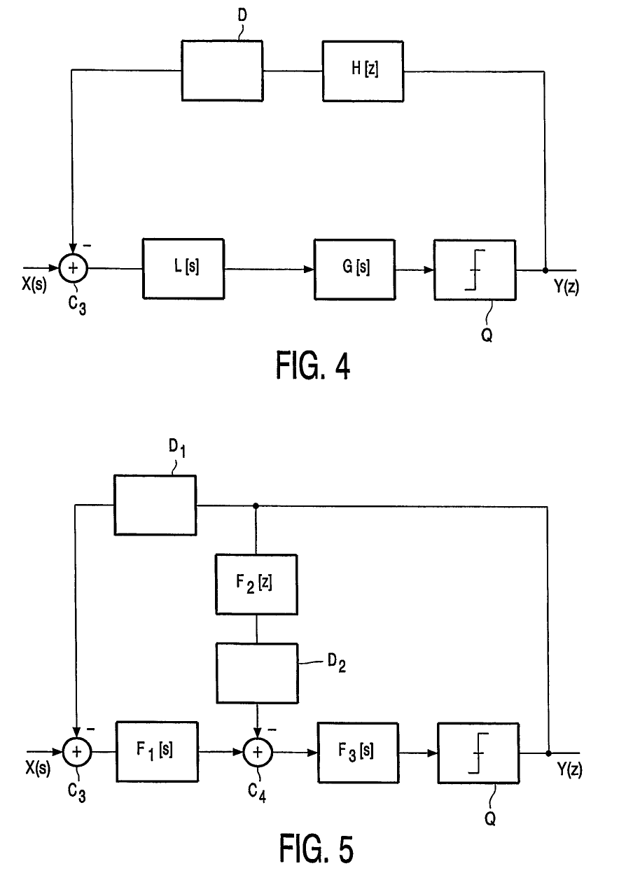

FIG. 4 a modification of the sigma-delta-modulator of FIG. 2,

FIG. 5 a modification of the sigma-delta-modulator of FIG. 3,

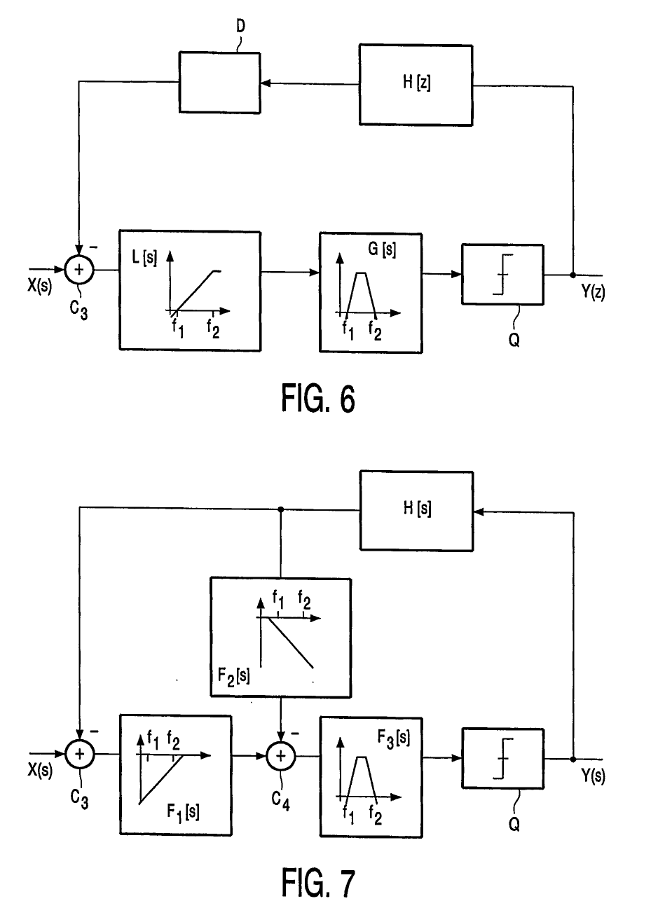

FIG. 6 the sigma-delta modulator of FIG. 4 for FM demodulation and

FIG. 7 the sigma-delta-modulator of FIG. 3 for FM demodulation.

The receiver of FIG. 1 comprises an amplifier A₁ that receives a band of communication channels from an antenna input. In a mixer M the amplified signals are mixed with a local oscillator frequency obtained from a tuned local oscillator O. In the arrangements to be described the oscillation frequency is equal to the carrier frequency of the desired channel, so as to transpose this channel to baseband (homodyne or zero-IF receiver), although the invention may also be used in a heterodyne receiver in which the desired communication channel is transposed to a suitable intermediate frequency signal. The output of the mixer M is again amplified in a second amplifier A₂ and subsequently applied to an analog to digital converter, which in this embodiment is constituted by a continuous time analog sigma-delta modulator SD. It may be observed that, in the arrangement of FIG. 1, the signals X(s) applied to the sigma delta modulator are not or only scarcely filtered so that the desired baseband channel is accompanied by interfering neighbor channels (interferers), which may have amplitudes that are much larger than the amplitude of the desired baseband channel. Moreover the amplitude of this baseband signal is strongly dependent on the reception conditions so that the dynamic range of the input signals applied to the sigma delta modulator SD is very large.

The input signal X(s) to the ΣΔ-modulator is applied to a first summing node C₁ and the output signal thereof is applied to a first integrator I₁ with transfer function 1/sτ₁. The output signal of the first integrator is applied to a second summing node C₂ whose output is coupled to a second integrator I₂ with transfer function 1/sτ₂. The output signals of the second integrator are fed to a clocked quantizer Q that converts the analog signals to a series of digital words with the sample rate of the clock-frequency. The quantizer Q may generate multi-bit words but conveniently the quantizer outputs single-bit words (bit-stream) in which case the quantizer may have the form of a one-level comparator. The output Y(z) of the quantizer is converted into analog pulses Y(s) in a digital to analog converter D and the analog pulses so obtained are applied through coefficient multipliers M₁ and M₂ with coefficients d₁ and d₂ to the summing nodes C₁ and C₂ respectively. In the arrangement of FIG. 1 the summing nodes C₁ and C₂ are subtracters with respect to the signals from the multipliers M₁ and M₂ but it will be apparent that, when in the DA-converter D or in the multipliers M₁ and M₂ the polarity of the signal is reversed, the output signals of the multipliers have to be added in the summing nodes C₁ and C₂. The output signals of the second integrator I₂ are applied, through a third multiplier M₃ with coefficient b, to a further adding input of the summing node C₁.

The digital output bit-stream of the ΣΔ-modulator SD is fed to a decimation filter F for converting the bit-stream to multi-bit words of reduced sample rate. The output of the filter F may be processed in further digital circuitry (not shown). Moreover this output is applied to an automatic gain control stage B that controls the magnitude of the coefficients b, d₁ and τ₁ in respectively the units M₃, M₁ and I₁ of the ΣΔ-modulator.

In operation the input signal X(s) is low pass filtered by the low pass filter constituted by the two integrators I₁ and I₂ and the feedback of the analog pulses Y(s) through the multipliers M₁ and M₂. The usual function of a EA-modulator is to digitize the signal and to shift the quantization noise associated therewith to the higher frequency range (noise-shaping) between the frequency band of interest and half the sample (clock) frequency of the quantizer. Additionally the low pass filter of FIG. 1 generates in the signal transfer of the ΣΔ-modulator a cut off frequency that approximately corresponds to the bandwidth of the desired channel, with the result that the desired channel is passed and the neighbor interferers are substantially suppressed and with the further result that the dynamic range of the signals within the feedback loop of the ΣΔ-modulator and thereafter is substantially reduced. In the arrangement of FIG. 1 the signal transfer function of the ΣΔ-modulator, which is responsible for the channel filtering, is approximately 1/(s τ₁d₂+d₁), which is a low pass filter of 1^{st} order.

The coefficient multiplier M₃ has substantially no effect on the channel filtering function of the ΣΔ-modulator but provides additional suppression of the quantization noise by implementing a local resonance close to the pass band of the desired signals.

A further substantial reduction of the dynamic range of the signals to be processed is obtained by automatic gain control. As already noted in the preamble to this patent application, this gain control can be performed inside the feedback loop of the ΣΔ-modulator as well as in front of the analog-to-digital converter. In the arrangement of FIG. 1 this is implemented by equally varying the three coefficients d₁, τ₁ and b in the units M₁, I₁ and M₃ respectively. It can be shown that with this measure the gain of the arrangement is changed while the characteristic frequencies that are responsible for the channel filtering and the noise shaping remain unaffected.

FIG. 2 shows an alternative for the ΣΔ-modulator of FIG. 1. In this arrangement the quantizer Q and the digital to analog converter D have the same function as the corresponding units of FIG. 1. A summing node C₃ subtracts the feedback signal from the input signal X(s) and the difference signal is applied through a noise-shaping low pass filter G to the quantizer Q. The channel filtering is performed by a high pass filter H in the feedback path from the DA-converter to the summing node C₃ and by a low-pass filter L in cascade with the filter G. When the transfer function of the high pass filter H is H(s) and that of the low pass filter L is L(s) then the product H(s).L(s) is constant (i.e. frequency independent). For instance H(s).L(s)=1.

When G(s) is the transfer function of the noise-shaping low pass filter G and when the combination of quantizer Q and digital to analog converter D is simulated by a linear amplifier with amplification A and a source of quantization noise ε, then the output signal Y(s) in the ΣΔ-modulator of FIG. 2 can be expressed as:

$$Y ( s ) = X ( s ) \frac{A . G ( s ) . L ( s )}{1 + A . G ( s ) . L ( s ) . H ( s )} + \frac{ɛ}{1 + A . G ( s ) . L ( s ) . H ( s )}$$

With L(s).H(s)=1 this becomes:

$$Y ( s ) = X ( s ) \frac{A . G ( s ) . L ( s )}{1 + A . G ( s ) .} + \frac{ɛ}{1 + A . G ( s ) .}$$

From the first term of the right hand side of this equation it follows that, when the amplification A is sufficiently high, the signal transfer is substantially only dependent from the channel filter L (and its counterpart H) and from the second term it follows that the noise-shaping is only dependent from the noise-shaping filter G. Therefore the arrangement of FIG. 2 allows optimizing the channel filtering and the noise-shaping independently from each other. The channel filtering is performed by proper dimensioning of the filters H and L, which may be of either first order or higher order or even band pass, and the noise-shaping is performed by proper dimensioning of the filter G which also may be of either first order or higher order or even band pass.

FIG. 3 shows another implementation of the ΣΔ-modulator. This arrangement has three filters F₁, F₂ and F₃ and an extra summing node C₄. The filter F₁ is placed between the output of the summing node C₃ and the positive input of the summing node C₄, The filter F₂ is placed between the output of the DA converter D and the negative input of the summing node C₄ and the filter F₃ is connected between the output of summing node C₄ and the quantizer input. The unfiltered output of the DA-converter is fed to the negative input of the summing node C₃. If the filters F₁, F₂ and F₃ have the transfer functions L(s), H′(s) and G(s) respectively, the same formula for the signal Y(s) and the same advantages as given above apply, except in that the product L(s).H(s) is replaced by the sum L(s)+H′(s). The implementation of the channel filters H′ can now be very simple, For instance, when L is a 1st order low pass RC-filter (τ=RC) with transfer

$$L ( s ) = \frac{1}{s τ + 1}$$

the filter H′ is an equally simple 1st order high pass RC-filter with transfer

$${H}^{′} ( s ) = \frac{s τ}{s τ + 1} .$$

The arrangement of FIG. 3 allows changing the implementation of the filters without changing the frequency characteristics of the ΣΔ-modulator as a whole. When for instance a differentiator with transfer function sr is added to both the filters F₁ and F₂ and a compensating integrator with transfer function 1/sτ to the filter F₃, then neither the channel filtering defined by F₁(s)/(F₁(s)+F₂(s)) nor the noise shaping, defined by (F₁(s)+F₂(s))*F₃(s) is changed. With the above given transfer functions of L(s) and H′(s) the transfer functions of F₁, F₂ and F₃ are now respectively:

$${F}_{1} ( s ) = s τ . \frac{1}{s τ + 1} = \frac{s τ}{s τ + 1} , {F}_{2} ( s ) = s τ . \frac{s τ}{s τ + 1} and {F}_{3} ( s ) = \frac{1}{s τ} . G ( s )$$

In a further conversion step a single high pass section in F3 replaces the two high pass sections of F₁ and F2. This results in:

$${F}_{1} ( s ) = 1 , {F}_{2} ( s ) = s τ , {F}_{3} ( s ) = \frac{1}{s τ} . \frac{s τ}{s τ + 1} G ( s ) = \frac{1}{s τ + 1} . G ( s ) .$$

Therefore the filter F₁ is merely an interconnection, the filter F₂ is a differentiator and the filter F₃ is the original low pass filter G in series with a low pass filter section L. In all three cases the quotient F₁(s)/(F₁(s)+F₂(S)), that determines the channel filtering, is equal to 1/(sτ+1) and the product (F₁(s)+F₂(S))*F₃(S) that determines the noise shaping, equals G(s). It may be observed that the multiplication factor τ of the differentiator determines the cut off frequency of the channel filter.

In the arrangements of FIGS. 2 and 3 gain control within the feedback loop of the ΣΔ-modulator is achieved by using a multiplying DA-converter D. When the quantizer Q delivers single-bit words, this DA-converter can be made very simple by means of a single current source that is AGC-controlled by the unit B and that is switched by the quantizer output pulses. When at higher levels of the input signal X(s) the current of this source is increased, the feedback is increased with the result that the amplification of the ΣΔ-modulator is decreased.

The function of the filters H and F₂ may be shifted behind the digital-to-analog converter D and then benefit from a digital implementation. This is shown in FIGS. 4 and 5. In these figures elements corresponding to those of FIGS. 2 and 3 are indicated by the same references. The filters itself are indicated by their transfer functions L(s), H[z], G(s) and F1(s), F₂[z] and F₃(s) respectively to indicate their continuous time and their discrete time nature. Care must then be taken that the transfer functions F1(s) and F2[z] of FIG. 5 (and L(s) and H[z] of FIG. 4) sufficiently match. The matching must be good enough so that the loop does not become unstable. The allowed mismatch depends on the available gain or phase margin of the original design.

In FIGS. 6 and 7 it is shown that FM demodulation can be realized with an analog to digital converter in accordance with the invention. This can be done by differentiation and consequent digital AM demodulation after the AD converter. According to the invention the differentiation can be merged into the sigma-delta loop. This is shown in the FIGS. 6 and 7 wherein elements corresponding with those of respectively FIGS. 4 and 3 have been given the same references. In the FIGS. 6 and 7 the transfer functions of the filters are indicated and drawn. It is shown that the transfer functions L(s) and F1(s) have a differentiating character between the frequency limits f₁ and f₂ of the input signal. The complementary transfer functions H[z] and F₂(s) have an integrating character between these frequency limits. Because in the input signal X(s) frequencies below f₁ do not occur, the noise shaping transfer functions G(s) and F₃(s) may have a band pass character so that part of the quantization noise is shifted to lower frequencies. It may be noted that filters L and F₁ with an integrating character may also implement FM demodulation, i.e. with transfer functions having a slope that is falling with rising frequency. The complementing filters H[z] and F₂(s) than have to have a differentiating character between the frequency limits f₁ and f₂.

The embodiments of the present invention described herein are intended to be taken in an illustrative and not a limiting sense. Various modifications may be made to these embodiments by those skilled in the art without departing from the scope of the present invention as defined in the appended claims.

It may be noted that the invention relates to homodyne receivers in which the desired channel is frequency-converted to baseband (zero-IF) as well as to heterodyne receivers with frequency-conversion of the desired channel to a suitable intermediate frequency band.

It may be observed that the embodiments discussed may be used in receivers for wireless communication, however it will be clear to those skilled in the art that the invention may be applied advantageously in other receivers, for instance receivers as used in TV systems for receiving terrestrial satellite broadcasted TV signals, or TV signals broadcasted via cable networks.

1. An analog-to-digital-converter comprising a sigma-delta modulator (SD) for analog to digital converting analog input signals, said sigma-delta modulator including a feedback loop with a forward path and a feedback path, wherein the forward path comprises a summing node (C₃) with a first input receiving the analog input signals, noise-shaping filtering means (G) coupled to the output of said summing node and a quantizer (Q) coupled to the output of the noise-shaping filtering means and wherein the feedback path is connected to supply output signals of the quantizer (Q) to a second input of the summing node (C₃), characterized in that both the forward path and the feedback path have filtering means that are arranged to additionally constitute a filtering signal transfer function.

2. An analog-to-digital-converter as claimed in claim 1 characterized in that the forward path of the feedback loop comprises, in addition to said noise shaping filtering means (G), a first filter (L) for constituting the filtering signal transfer function, that the feedback path of the feedback loop comprises a second filter (H) for constituting the filtering signal transfer function and that the product of the transfer function of the first filter and the transfer function of the second filter is substantially frequency-independent.

3. An analog-to-digital converter as claimed in claim 1 having an input for receiving an input signal X(s) and an output for providing an output signal Y(z), the sigma delta modulator comprising:
a summing node (C₃), a first filter (L), a second filter (H), a third filter (G), a comparator (Q), and a digital-to-analog converter (D);
means to couple the input of the analog-to-digital converter and an output of the second filter (H) to the summing node;
means to cascade the first filter (L) with the third filter (G);
means to couple the cascade of said first and third filters between an output of the summing node and an input of the comparator (Q);
means to couple an output of the comparator (Q) to the output of the analog-to digital converter and to an input of the digital-to-analog converter (D);
means to couple an output of the digital-to-analog converter (D) to an input of the second filter (H);
whereby the product of the transfer function of the first filter (L) and the transfer function of the second filter (H) is frequency independent.

4. An analog-to-digital converter as claimed in claim 2 characterized in that said product is substantially equal to ‘one’.

5. An analog-to-digital converter as claimed in claim 1 characterized by a second summing node (C₄) with first and second inputs and an output, by a first filter (F₁) with transfer function F₁(s) connected between the output of the first mentioned summing node (C₃) and the first input of the second summing node (C₄), a second filter (F₂) with transfer function F₂(s) connected between the output of the quantizer (Q) and the second input of the second summing node (C₄) and a third filter (F₃) with transfer function F₃(s) between the output of the second summing node (C₄) and the input of the quantizer (Q), wherein the transfer function F₁(s)/(F₁(s)+F₂(s)) provides the filtering signal transfer function of the analog-to-digital-converter.

6. An analog-to-digital converter as claimed in claim 5, characterized in that the transfer function F₂(s) of the second filter (F₂) is complementary to the transfer function F₁(s) of the first filter (F₁) whereby the sum of the transfer functions F₁(s) and F₂(s) is substantially frequency independent and the third filter (F₃) provides the noise shaping function.

7. An analog-to-digital converter as claimed in claim 1, having an input for receiving an input signal (X(s)) and an output for providing an output signal (Y(z)), the sigma delta modulator comprising:
means for connecting an input signal (X(s)) to a first summing node (C₃);
a first filter (F₁) having an input coupled to the first summing node (C₃) and an output coupled to a second summing node (C₄),
a digital-to-analog converter (D) having an input coupled to the output of the analog-to-digital converter and an output coupled to an input of a second filter (F₂);
an output of the second filter (F₂) being coupled to the second summing node (C₄);
a third filter (F₃) having an input coupled to the second summing node (C4) and an output coupled to the output of the analog-to-digital converter via a quantizer (Q);
the output of the digital-to-analog converter (D) further being coupled to the first summing node (C₃);
whereby the sum of the transfer functions of the first and second filters is substantially frequency independent.

8. An analog-to-digital converter as claimed in claim 6, characterized in that the sum of the transfer functions of the first and second filters is substantially equal to ‘one’.

9. An analog-to-digital converter as claimed in claim 1 characterized in that the sigma-delta modulator comprises one or more gain controlled stages (M₁, I₁, M₃, D).

10. An analog-to-digital converter as claimed in claim 2, characterized in that the second filter (H, F₂) is a digitally implemented filter having an input connected to the output of the quantizer and an output coupled to at least one summing node through a digital to analog converter.

11. An analog-to-digital converter as claimed in claim 1 having an input for receiving an input signal X(s) and an output for providing an output signal Y(z), the analog-to-digital converter comprising:
a first summing node (C₃), a second summing node (C₄), a first digital-to-analog converter (D₁), a second digital-to-analog converter (D₂), a first filter (F₁), a second filter (F₂), a third filter (F₃), and a quantizer (Q);
means for coupling an input of the first digital-to-analog converter (D₁) to an output of the quantizer(Q) and to couple an output of the first digital-to-analog converter (D₁) to the first summing node;
means to couple an input of the first filter to the first summing node (C₃) and to couple an output of the first filter (F₁) to the second summing node (C₄);
means to couple an input of the second filter (F₂) to the output of the converter and to couple an output of the second filter to the input of the second digital-to-analog converter (D₂);
means to couple an output of the second digital to analog converter (D₂) to the second summing node (C₄);
means to couple an input of the third filter (F₃) to the second summing node (C₄) and to couple an output of the third filter to an input of the quantizer (Q);
means to couple the output of the analog-to-digital converter to the output of the quantizer (Q);
wherein the sum of the transfer function of the first filter and the analog version of the transfer function of the second filter is constant within the loop bandwidth of the converter.

12. A receiver comprising an analog-to-digital converter as claimed in claim 1.

13. A receiver as claimed in claim 12, characterized in that it comprises means for receiving a plurality of communication channels, a mixer (M) for frequency-converting at least part of said communication channels, the analog-to-digital-converter for analog to digital converting output signals of the mixer wherein the signal transfer function of the sigma delta modulator has a pass band that substantially corresponds with the frequency band of the desired channel while the interferer channels beyond that pass band are substantially attenuated.

14. A receiver as claimed in claim 12, characterized in that the input signal is an FM-modulated analog signal and that, for the purpose of FM-demodulation of the signal, one of the first and second filters is a differentiator and the other of the first and second filters is an integrator within the frequency band of the input signal.
